(19) United States
(12) Patent Application Publication
(10) Pub. No.: US 2026/0026034 A1
(43) Pub. Date: Jan. 22, 2026

(54) CONTACT-ON-POLY SPLIT GATE FOR TRANSISTOR

(71) Applicant: Alpha and Omega Semiconductor International LP, Toronto (CA)

(72) Inventors: Shekar Mallikarjunaswamy, San Jose, CA (US); Shanghui Tu, San Diego, CA (US)

(21) Appl. No.: 18/780,225

(22) Filed: Jul. 22, 2024

(51) Int. Cl. H01L 29/78; H01L 23/528; H01L 29/40; H01L 29/423; H01L 29/49

(52) U.S. Cl. CPC H10D 30/65; H01L 23/528; H10D 64/111; H10D 64/518; H10D 64/661; H10D 64/665

(57) ABSTRACT

A planar gate transistor device, comprising a semiconductor substrate and a conductive gate electrode formed over the semiconductor substrate. A conductive split gate electrode is formed over the semiconductor substrate proximate a side of the conductive gate electrode near a drain contact and a conductive contact plug is formed over the split gate electrode.

### FIELD OF THE DISCLOSURE

Aspects of the present disclosure relate to transistor devices, specifically aspects of the present disclosure relate planar gate transistors.

### BACKGROUND OF THE DISCLOSURE

Traditional single gate transistors such as Laterally Diffused Metal-Oxide Semiconductor Field Effect (LD-MOS) transistors suffer from high Gate-Drain Charge (Q_{gd}) due to a wide overlap between the gate electrode and the underlying drift region in the semiconductor substrate. Additionally typical single gate devices create a high electric field in the semiconductor substrate at the edge of the gate causing an eventual breakdown and hot carrier injection at higher voltages. Thus, single gate transistors of traditional design may not be suitable for high voltage applications.

One solution to these issues is a conventional split gate structure such as shown in FIG. 1. The transistor of FIG. 1 includes the typical transistor doped regions in the semiconductor substrate composition found in LDMOS devices such as a p-type semiconductor substrate base region 101, an n-type isolation region 102, p-type lower drift region 103, n-type upper drift region 104, p-type well region 105, n-type source contact region 106 and n-type drain contact region 107. The p-type well region 105 includes a well region extension 120 which may have the doping concentration of the epitaxial layer before doping of additional regions or the starting substrate before doping of additional regions. Here structures formed above the substrate composition include oxide insulation layer 110, gate electrodes 108, split gate electrodes 109, conductive source contacts 112, and conductive drain contacts 111. The oxide insulation layer 110 insulates the gate electrodes 108 and split gate electrodes 109 from each other and from the semiconductor substrate composition. Each conductive drain contact 111 makes physical and conductive contact with the substrate composition at a corresponding drain contact region 107. Similarly, each conductive source contact 112 makes physical and conductive contact with a corresponding source region 106 in the semiconductor substrate composition. Additionally, a source metal layer 114, split gate metal layer 116 and drain metal layer 115 are located above the insulation layer. The source metal layer 114 is in conductive contact with the source contact 112. The drain metal layer 115 makes conductive contact with the drain contact 111. The split gate metal layer 116 is conductively coupled to the split gate 109 out of the plane of FIG. 1 as illustrated by the dashed line 113, e.g., by small vias through the oxide insulation layer 110 to the split gate. Similarly, the split gate metal 116 is conductively coupled 117 to the source metal 114 out of view as shown by the dashed line by for example conductive wires. Here the split gate design has several disadvantages. First the split gate design is constrained by width, space and silicide design rules that result in degradation of on resistance (Ron) and Hot Carrier Injection (HCI). Additionally, the split gate electrode is not effective in shielding the drain contact or drain metal from the gate.

Another prior solution is to use a contact field plate structure as depicted in FIG. 2A. In this implementation a contact field plate 204 is used with a large single gate 201. The large single gate 201 is covered with a nitride layer 202 embedded in an oxide insulation layer 203. As can be seen, the contact field plate 204 extends from the top surface of the oxide insulation layer 203 into the nitride layer 202. Similar to the split gate implementations, the contact field plate 204 is conductively coupled with source contact 112 as indicated by the dashed line 205, e.g., through a wire or conductive lead to the source metal shown out of plane in FIG. 2A. In this implementation the contact field plate 204 is a small conductive field plate that is approximately the same width than the drain contact 111 and the source contact 112. The small conductive contact field plate 204 represents a compromise between field plate effectiveness, contact size, contact over etch time and silicide block etch thickness. Due to its small size, contact field plate 204 plate provides a small field plate effect in the semiconductor substrate.

An alternative implementation shown in FIG. 2B uses a wide contact field plate 210 that is wider than the drain contact 111 or the source contact 112. As shown the wide contact field plate 210 extends from the single gate electrode 201 above the nitride layer 202 to above a portion of the semiconductor substrate composition. This implementation provides a better field plate effect compared to the small contact field plate shown in FIG. 2A and provides good shielding between drain and gate. On the downside, this wide field plate requires a wider etch to create, which makes it difficult to manufacture because it is easy to etch too deep (Y-direction) during manufacturing and destroy the device. Consequently, the wide contact field plate 210 must be made in a thick portion of the oxide layer above the gate.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1 is a side cross-section diagram of a prior art split-gate LD-MOSFET device.

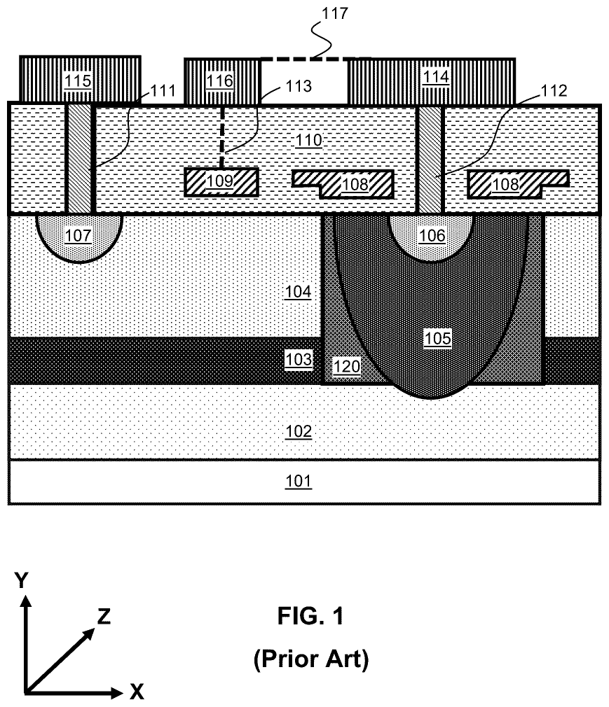

FIG. 2A is a side cross-section diagram of a prior art LD-MOSFET with small contact field plate structure.

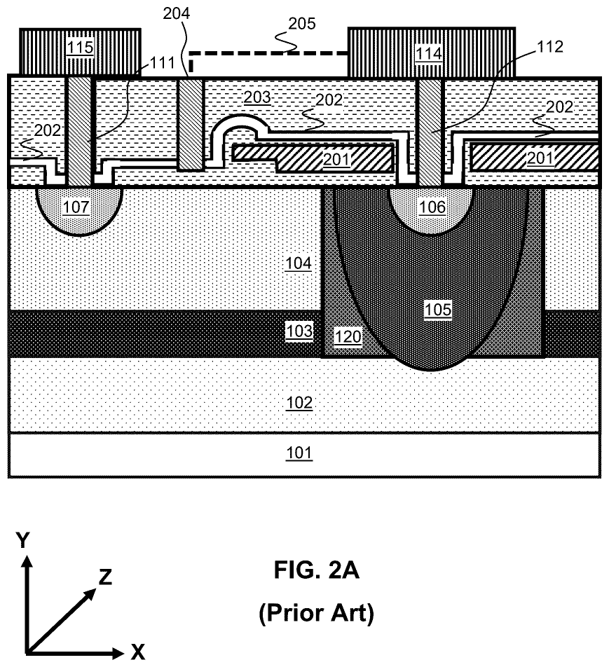

FIG. 2B is a side cross-section diagram of a prior art LD-MOSFET with wide contact field plate structure.

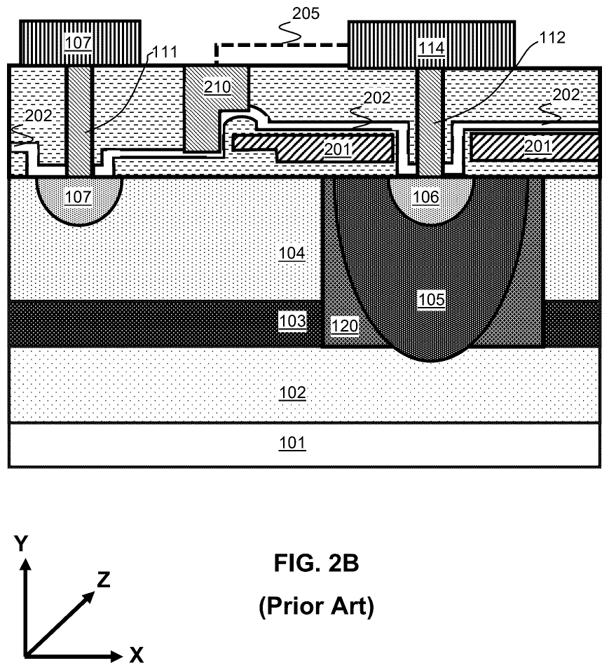

FIG. 3A is a side cross-section diagram of a split gate transistor device with a contact plug over the split gate according to an aspect of the present disclosure.

FIG. 3B is a side cross-section diagram of a split gate transistor device with a contact plug in physical and conductive contact with split gate at a silicided contact interface according to an aspect of the present disclosure.

FIG. 3C is a side cross-section diagram of a split gate transistor device with a contact plug in physical and conductive contact with split gate at an unsilicided contact interface according to an aspect of the present disclosure

FIG. 4A is a side cross-section diagram of a split gate transistor device with a wide contact plug over the split gate according to an aspect of the present disclosure.

FIG. 4B is a side cross-section diagram of a split gate transistor device with a wide contact plug in physical and conductive contact with split gate at a silicided contact interface according to an aspect of the present disclosure.

FIG. 4C is a side cross-section diagram of a split gate transistor device with a wide contact plug in physical and conductive contact with split gate at an unsilicided contact interface according to an aspect of the present disclosure.

FIG. 5A is a side cross-section diagram of a split gate transistor device with two or more contact plugs over the substrate composition according to an aspect of the present disclosure.

FIG. 5B is a side cross-section diagram of a split gate transistor device with two or more contact plugs and at least one contact plug in physical and conductive contact with split gate at a silicided contact interface according to an aspect of the present disclosure.

FIG. 5C is a side cross-section diagram of a split gate transistor device with two or more contact plugs and at least one contact plug in physical and conductive contact with split gate at an unsilicided contact interface according to an aspect of the present disclosure.

FIG. 6A is a side cross-section diagram of a split gate transistor device with a wide contact plug over the split gate and one or more other contact plugs over the semiconductor substrate composition according to an aspect of the present disclosure.

FIG. 6B is a side cross-section diagram of a split gate transistor device with a wide contact plug in physical and conductive contact with split gate a silicided contact interface and one or more other contact plugs over the semiconductor substrate composition according to an aspect of the present disclosure.

FIG. 6C is a side cross-section diagram of a split gate transistor device with a wide contact plug in physical and conductive contact with split gate an unsilicided contact interface and one or more other contact plugs over the semiconductor substrate composition according to an aspect of the present disclosure.

FIG. 7 is a side cross-section diagram of a split gate transistor device with a contact plug over the split gate with a portion of the split gate electrode formed over the gate electrode according to an aspect of the present disclosure.

FIG. 8 is a side cross-section diagram of a split gate transistor device with a contact plug over the split gate conductively coupled to the gate by at least one diode according to an aspect of the present disclosure.

FIG. 9A is a side cross-section diagram of a split gate transistor device with a contact plug over the split gate and extended surface drift implant region according to an aspect of the present disclosure.

FIG. 9B is a side cross-section diagram of a split gate transistor device with a contact plug over the split gate and extended deep drift implant region according to an aspect of the present disclosure.

FIG. 10 is a top-down view of a split gate transistor device with a contact plug and split gate according to an aspect of the present disclosure.

FIG. 11 is a top-down view of a split gate transistor device with a doped split gate electrode in contact with a doped gate electrode forming a diode between the split gate electrode and a the gate electrode according to an aspect of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, examples of embodiments of the invention described below are set forth without any loss of generality to, and without imposing limitations upon, the claimed invention. In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present disclosure can be positioned in a number of different orientations, the directional terminology is used for purposes of illustration and is in no way limiting. Additionally, it should be understood that the term “conductively coupled” means that the first component that is conductively coupled to a second component may receive electrical energy from the second element by way of physical contact but that electrical energy may pass through any number of intermediate components (such as wires, passive devices etc.) before reaching the first element. It is to be understood that other embodiments may be utilized, and structural or logical changes may be made without departing from the scope of the present invention. The following detailed description, therefore, is not to be taken in a limiting sense, and the scope of the present invention is defined by the appended claims.

The disclosure herein refers to a semiconductor material, such as silicon, doped with ions of a first conductivity type or a second conductivity type. The ions of the first conductivity type may be opposite ions of the second conductivity type. For example, and without limitation, in some implementations, ions of the first conductivity type may be n-type, which contribute negative charge carriers, e.g., electrons, when doped into silicon. In such implementations, ions of the first conductivity type may include phosphorus, antimony, bismuth, lithium, and arsenic. In such implementations, ions of the second conductivity may be p-type, which create holes for charge carriers when doped into silicon and in this way are referred to as being the opposite of n-type. P-type type ions include boron, aluminum, gallium, and indium. While the above description referred to n-type as the first conductivity type and p-type as the second conductivity type the disclosure is not so limited, p-type may be the first conductivity type and n-type may be the second conductivity type. Furthermore, semiconductor materials other than silicon may be used in MOSFET devices in accordance with aspects of the present disclosure.

In the following Detailed Description, reference is made to the accompanying drawings, which form a part hereof, and in which are shown by way of illustration of specific embodiments in which the invention may be practiced. For convenience, use of + or − after a designation of conductivity or net impurity carrier type (p or n) refers generally to a relative degree of concentration of a designated type of net impurity carriers within a semiconductor material. In general, terms, an n+ material has a higher n type net dopant (e.g., electron) concentration than an n material, and an n material has a higher carrier concentration than an n− material. Similarly, a p+ material has a higher p type net dopant (e.g., hole) concentration than a p material, and a p material has a higher concentration than a p− material. It is noted that what is relevant is the net concentration of the carriers, not necessarily dopant concentration. For example, a material may be heavily doped with n-type dopants but still have a relatively low net carrier concentration if the material is also sufficiently counter-doped with p-type dopants. As used herein, a concentration of dopants less than about 1e¹⁴ cm⁻³ may be regarded as “lightly doped” and a concentration of dopants greater than about 1e¹⁶ cm⁻³ may be regarded as “heavily doped”.

An improvement to Ron and HCI and better shielding between the drain contact and drain metal from the gate electrode may be obtained using a contact plug over split gate design according to aspects of the present disclosure. Additionally, the conductive contact plug over split gate design provides for an improved process flow as the split gate may serve as an etch-stop for the contact plug reducing the likelihood of destroying the device during creation of the plug trench. Furthermore, in the contact plug over split gate design, the split gate contact does not need to be silicided unlike the prior art split gate design, this reduces many design rule limitations that the prior art split gate design incurred due to the need for a silicided split gate contact. As used herein, and as generally understood in the art of semiconductor processing, siliciding generally refers to depositing metal on silicon to form compounds known as silicides.

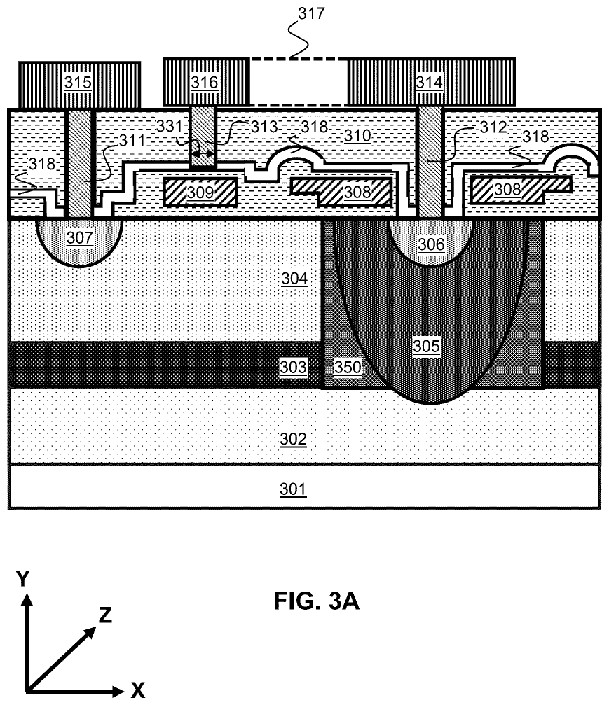

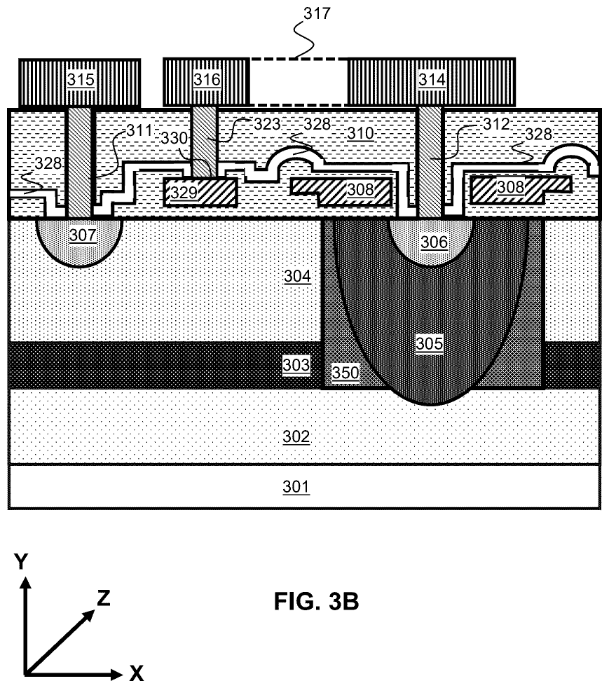

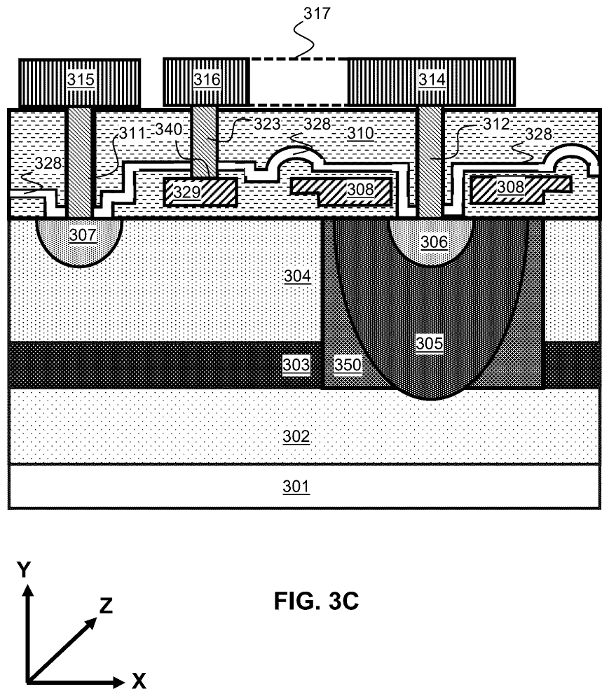

FIG. 3A is a side cross-section diagram of a split gate transistor device with a contact plug over the split gate according to an aspect of the present disclosure. As shown an isolation region 302 doped with ions of a first conductivity type may be formed on top of a base substrate 301 doped with ions of a second conductivity type. In some implementations, the isolation region 302 may be formed by high energy ion implantation with ions of the first conductivity type. A lower drift region 303 of the second conductivity type may be co-implanted into an area of substrate material above the isolation region 302 with ions of the second conductivity type. An upper drift region 304 may be doped into a region of substrate above the lower drift region 303 with ions of the first conductivity type. A well region 305 may be doped with ions of the second conductivity type into the substrate composition through the upper drift region 304, lower drift region 303 and into a portion of the isolation region 302. The well region 305 may include a well region extension 350 which may have the doping concentration of the epitaxial layer before doping of additional regions or the starting substrate before doping of additional regions. A source region 306 is doped into the well region with ions of the first conductivity type. A drain region 307 may be doped into the upper drift region 304 with ions of the first conductivity type.

Alternatively, the isolation region 302 may be implanted as a buried layer before growing additional substrate material over the isolation region via epitaxial processes. These additional layers may be doped to become the lower drift region 303, upper drift region 304 well region 305, source region 306 and drain region 307. In yet other implementations the isolation region may be omitted.

An insulation layer 310 may be formed over the substrate composition. The insulation layer 310 may be made from an oxide, such as silicon dioxide or another electrically insulating material. The gate electrode 308 may be embedded in the insulation layer 310. Similarly, the split gate electrode 309 may be embedded in the insulation layer next to the gate electrode on the side of the gate electrode proximal to the drain contact 311. The gate electrode 308 and split gate electrode 309 may be made from a conductive material for example and without limitation polycrystalline silicon or a metal such as copper, or a barrier metal such as titanium nitride, chromium, bismuth etc. In implementations with a polycrystalline silicon gate and/or split gate, the gate electrode 308 may be n-doped polycrystalline silicon and the split gate electrode 309 may be n-doped, p-doped or undoped polycrystalline silicon. A nitride layer 318 may be formed over the gate electrode 308 and the split gate electrode 309 in the insulation layer 310.

A drain contact 311 may be formed through the insulating layer 310 to make conductive contact with the drain region 307. The drain contact may be formed from a conductive material such as a metal with barrier metal for example and without limitation tungsten with titanium nitride barrier layer. Similarly, a source contact 312 may be formed through the insulating layer 310 to make conductive contact with the source region 306. The source contact likewise may be formed from a conductive material such as a metal with barrier metal for example and without limitation tungsten with titanium nitride barrier layer. A source metal layer 314 may be formed on top of the insulation layer 310 and is connected to the source contact 312. In this implementation the source metal 314 is conductively coupled to a split gate metal layer 316. The source metal layer 314 may make conductive contact with the split gate metal 316 via wires or a metal bus bar out of plane of the current view as indicated by the dashed lines 317. In implementations with the metal bus bar 317, the bus bar may be a region of top metal between 50 and 60 micrometers wide which makes contact between the split gate metal layer 316 and the source metal layer 314. The split gate metal 316 may be connected to a conductive contact plug 313 and in the implementation shown may complete a circuit that conductively couples the conductive contact plug and the split gate to the source contact and thus source potential.

The conductive contact plug 313 is formed through the insulation layer 310 into the nitride layer 318 over the split gate. In the implementation shown the conductive contact plug 313 is conductively coupled to the split gate in split gate contact areas not shown in FIG. 3A. The split gate contact areas (not shown) may be located on the end of fingers formed by the split gate around the drain region. In other regions the conductive contact plug 313 may not breach the nitride layer over the split gate 309 and may be insulated from the split gate in those regions and may also engage in capacitive coupling with the split gate. The split gate may be formed by reactive ion etching of the insulation layer followed by deposition or plating with a conductive material. The conductive contact plug may be made from metal with a barrier metal for example and without limitation tungsten with a titanium nitride, Tungsten-nitride, Tantalum, Ruthenium, Tantalum-nitride, or Indium-oxide outer layer. Alternatively, the conductive plug may be made of polycrystalline silicon. In the implementation illustrated in FIG. 3A, the conductive contact plug 313 is small having a horizontal (x-direction) width 331 along the view plane of less than 0.09 micrometers and preferably around 0.08 micrometers. The small conductive contact plug here 313 may be slightly less wide than the source contact 312 or drain contact 311 which have a horizontal (x-direction) width of between 0.1 micrometers and 0.3 micrometers. Alternatively, the conductive plug 313, source contact 312 and drain contact 311 may all be of equivalent width for example and without limitation less than 0.09 micrometers wide. The conductive plug 313, source contact 312, and drain contact 311 may all have equivalent z-direction lengths. Each of conductive plug 313, Source contact 312, and drain contact 311 may be arranged as an array in the Z-direction with multiple contacts to their corresponding contact region. In some implementations each contact in the array may have an equivalent z-direction length to the horizontal (x-direction) width, for example and without limitation 0.09 micrometers thus in one example placing the overall dimension of each contact in the array at 0.09×0.09 μm. Alternatively, the conductive plug 313, Source contact 312, and drain contact 311 may be arranged as bar contacts meaning in the Z-direction they may be continuous having a Z-direction length chosen to run the length of the corresponding contact region for example and without limitation the conductive plug 313, Source contact 312, and drain contact 311 may each have a Z-direction length of between 30 to 50 micrometers. In some implementations the bar contact may be elongated to run to fit the layout of their corresponding contact regions.

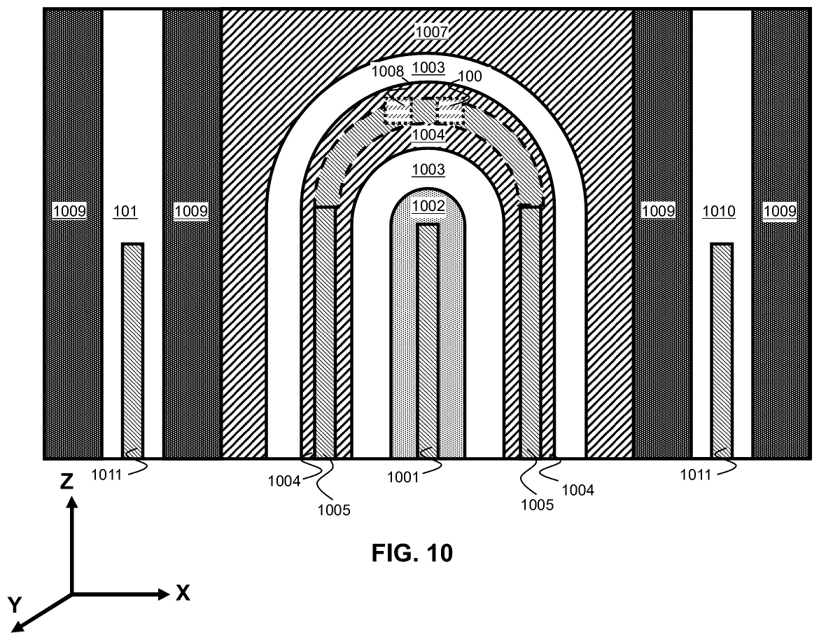

In an alternative implementation according to aspects of the present disclosure and as shown in FIG. 3B the contact plug is in physical and conductive contact with the split gate. Here, the contact plug 323 pierces through the nitride layer 328 and makes conductive and physical contact with split gate 329 at a silicided contact interface 330. The contact plug 323 follows over top the split gate 329 as will be seen in FIG. 10 and makes physical and conductive contact throughout its area at the contact interface 330. This implementation may be preferable in some use cases where better conductive coupling of the source potential to the split gate poly and reduced RC delay during switching are desired. In FIG. 3C the contact plug 323 pierces through the nitride layer 328 and makes conductive and physical contact with split gate 329 at an unsilicided contact interface 340.

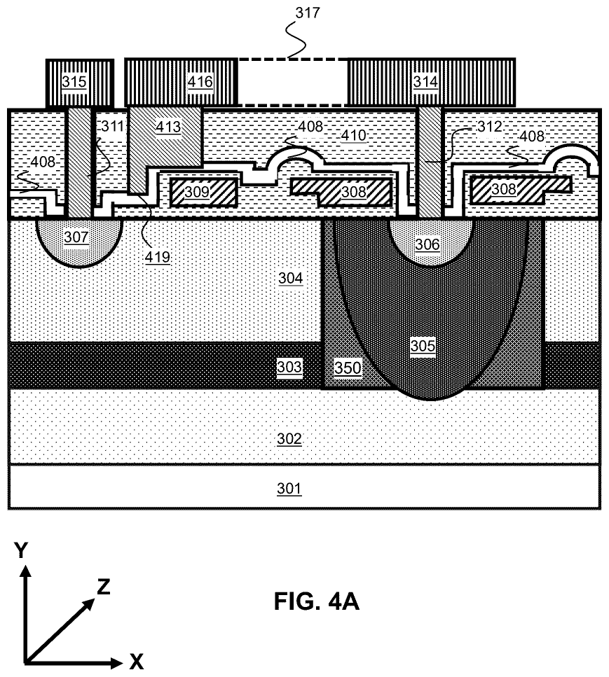

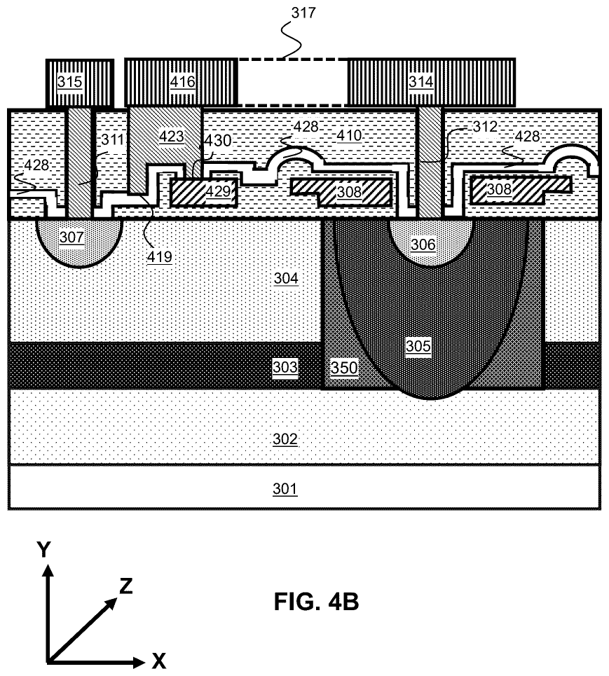

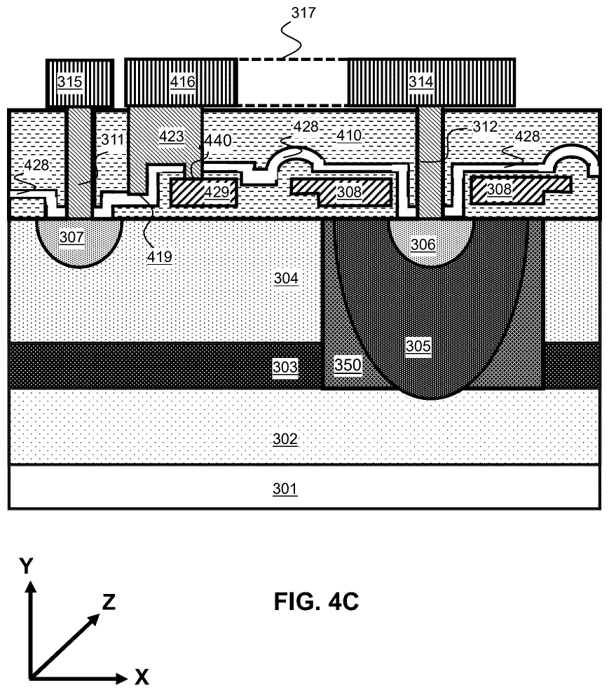

FIG. 4A is a side cross-section diagram of a split gate transistor device with a wide contact plug over the split gate according to an aspect of the present disclosure. In this implementation the contact plug 413 is wider than the previous implementation and may for example and without limitation be greater than 0.1 micrometers, preferably between 0.1 and 0.3 micrometers. The contact plug 413 is thus wider than the source contact 312 and the drain contact 311 which are generally less than 0.1 micrometers in horizontal (x-direction) width in advanced transistors such as those created with 90 nm processes and below. The wide contact plug 413 here is formed in the insulation layer 410 and intersects the top of the nitride layer 408 without piercing it or touching the split gate 309 beneath. To accommodate the wide contact plug 413 the split gate metal layer 416 may be dimensioned wide enough to at least cover the wide contact plug 413. Similar to the implementation of FIG. 3A, in this implementation, the wide contact plug 413 is conductively coupled with the split gate 309 at one or more split gate contact areas which are not shown in this drawing. Additionally, a portion 419 of the wide contact plug 413 may extend beyond the split gate to overhang part of the upper drift region 304 of the substrate composition. This may improve the drain to source Breakdown voltage (BVdss) and HCI as the overhanging portion 419 of the wide contact plug may act as an additional field plate.

FIG. 4B is a side cross-section diagram of a split gate transistor device with a wide contact plug in physical and conductive contact with the split gate according to an aspect of the present disclosure. Similar to the implementation of FIG. 3B, a portion of the wide contact plug 423 pierces the nitride layer 428 to make physical and conductive contact with the split gate 429 at a contact interface 430. The wide contact plug 423 follows over top the split gate 429 and makes physical and conductive contact throughout its area at the silicided contact interface 430. This implementation may be preferable in some use cases where better conductive coupling of the source potential to the split gate poly and reduced RC delay during switching are desired. In FIG. 4C a portion of the wide contact plug 423 pierces the nitride layer 428 to make physical and conductive contact with the split gate 429 at a contact interface 430. The wide contact plug 423 follows over top the split gate 429 and makes physical and conductive contact throughout its area at the unsilicided contact interface 440.

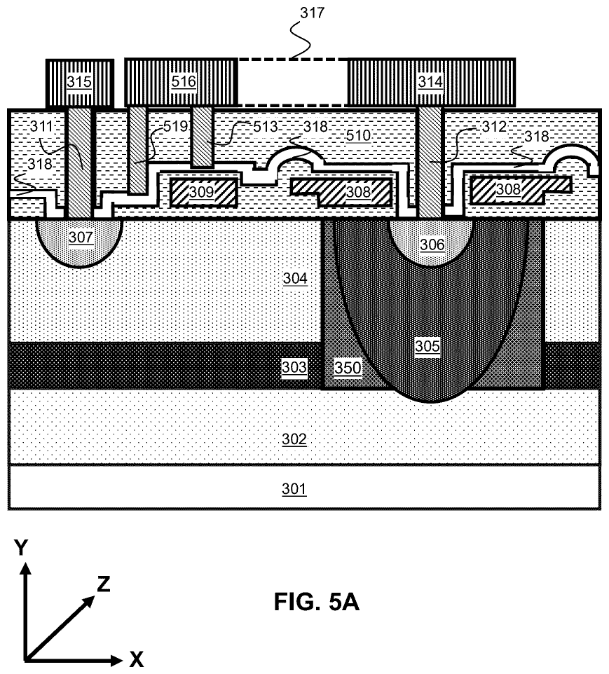

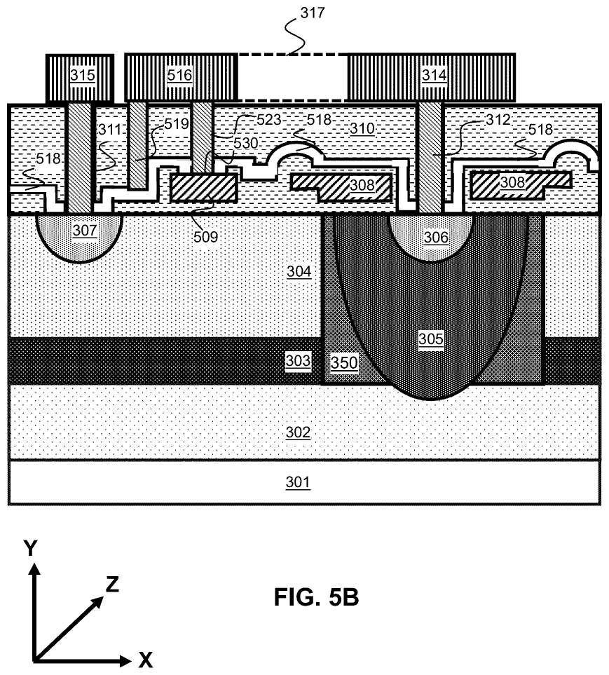

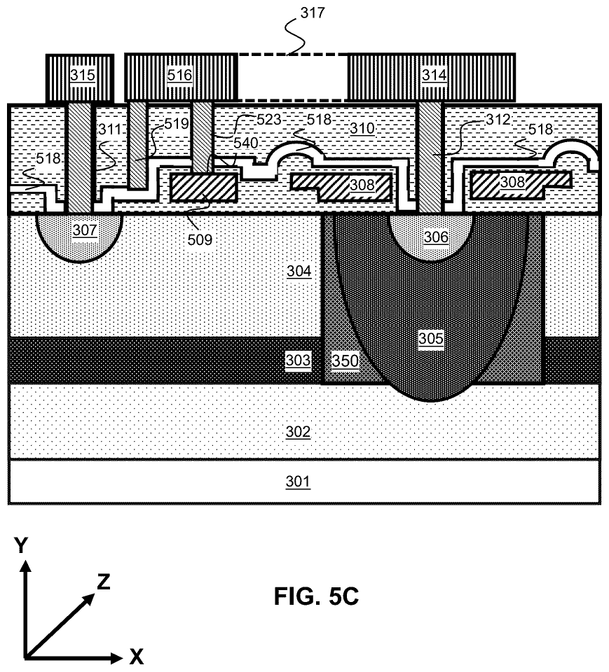

FIG. 5A is a side cross-section diagram of a split gate transistor device with two or more contact plugs over the substrate composition according to an aspect of the present disclosure. In this implementation a first contact plug 513 may be formed in the insulation layer 510 intersecting the nitride layer 318 over the split gate 309. A second contact plug 519 may be formed in the insulation layer 510 intersecting the nitride layer 318 over the upper drift region 304 of the semiconductor substrate composition. Similar to the implementation shown in FIG. 3A, the active contact over the split gate is conductively coupled to the split gate through an active contact area which is not shown. In some alternative implementations there may be more than two contact plugs for example and without limitation, three contact plugs with two over the substrate composition and one over the split gate, or four contact plugs with one over the split gate and three over the substrate composition etc.

The implementation shown in FIG. 5A may be useful for high voltage transistor devices that have a larger cell pitch than low voltage devices and thus have more room for additional contact plugs. As used herein, the term “cell pitch” refers to the size of the cell that can be repeated to form an array. The typical cell pitch of low voltage devices may be 1.5 micrometers to 1.6 micrometers which corresponds to roughly to a 25 Volt breakdown voltage while a high voltage device may have a large cell pitch of around 10 micrometers to 150 micrometers which corresponds to roughly a 100 Volt to 1000 Volt breakdown voltage, respectively if properly designed. Additionally, here, the split gate metal 516 may have dimensions large enough to cover and make conductive contact with the two or more contact plugs. The one or more additional contact plugs 519 may act as field plates over the substrate composition further improving the BVdss and HCI characteristics of the device.

FIG. 5B is a side cross-section diagram of a split gate transistor device with two or more contact plugs and at least one contact plug in physical and conductive contact with split gate according to an aspect of the present disclosure. In this implementation like the implementation shown in FIG. 3B, one of the two or more contact plugs 523 pierces the nitride layer 518 making physical and conductive contact with the split gate 509 at a contact interface 530. The contact plug 523 that pierces the nitride layer follows over top the split gate 509 and makes physical and conductive contact throughout its area at the silicided contact interface 530. This implementation may be preferable in some use cases where better conductive coupling of the source potential to the split gate poly and reduced RC delay during switching are desired. In FIG. 5C one of the two or more contact plugs 523 pierces the nitride layer 518 making physical and conductive contact with the split gate 509 at a contact interface 530. The one of the two or more contact plug 523 follows over top the split gate 509 and makes physical and conductive contact throughout its area at the unsilicided contact interface 540.

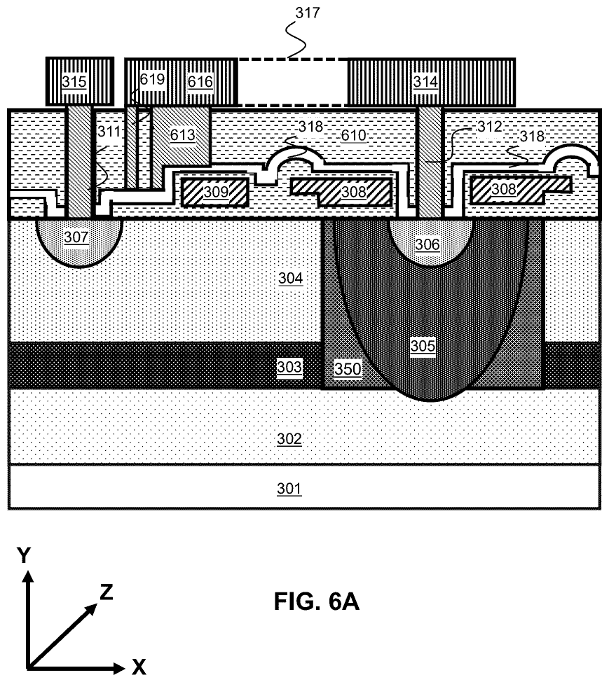

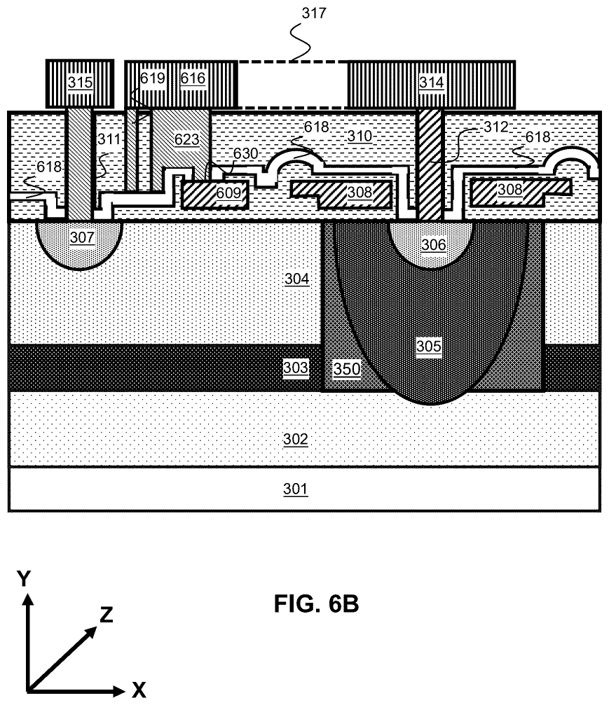

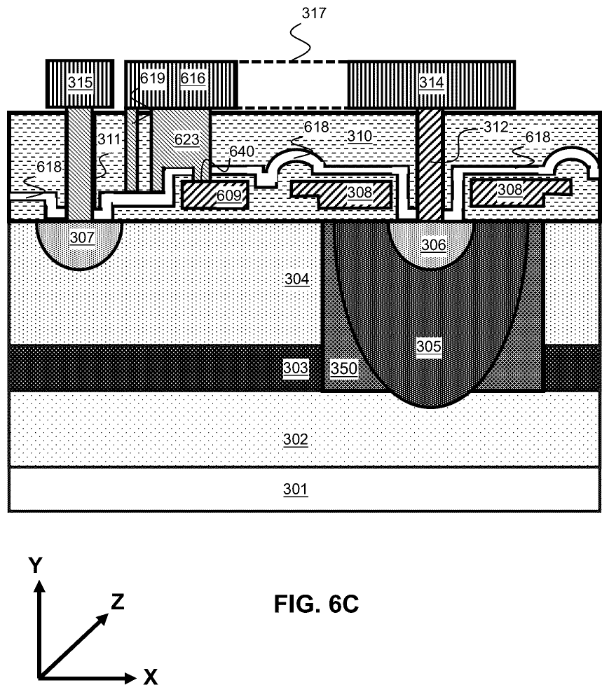

FIG. 6A is a side cross-section diagram of a split gate transistor device with a wide contact plug over the split gate and one or more other contact plugs over the semiconductor substrate composition according to an aspect of the present disclosure. In this implementation a wide contact plug 613 is formed in the insulation layer 610 over the split gate 309 and one or more other additional contact plugs 619 are formed in through the insulation layer 610 over the upper drift region 304 of the substrate composition. Similar to the implementation in FIG. 4A, the wide contact plug 613 intersects but does not pierce the nitride layer 318 over the split gate and extends from a portion of the split gate to over upper drift region 304 of the substrate composition. The wide contact plug 613 may have a horizontal (x-direction) width of between 0.1 and 0.4 micrometers and the one or more other contact plugs may have a horizontal (x-direction) width of less than 0.09 micrometers. The one or more other contact plugs 619 may also intersect but not pierce the nitride layer 318 over the substrate composition. The split gate metal 616 may be dimensioned to make conductive contact with both the wide contact plug 613 and the one or more other contact plugs 619. In this implementation the portion of the wide contact plug 613 overhanging the substrate composition and the one or more other contact plugs 619 contribute to the field plate effect. Furthermore, the wide contact plug 613 is conductively coupled with the split gate electrode 309 at one or more active contact regions (not shown here) on the split gate and thus regions of the wide contact plug over the split gate electrode may contribute to capacitive coupling of the wide contact plug to the split gate electrode.

FIG. 6B is a side cross-section diagram of a split gate transistor device with a wide contact plug in physical and conductive contact with split gate and one or more other contact plugs over the semiconductor substrate composition according to an aspect of the present disclosure. This implementation is like the implementation shown in FIG. 6A except that the wide contact plug 623 pierces the nitride layer 618 and makes physical and conductive contact with the split gate electrode 609 at a silicided contact interface 630. The wide contact plug 623 follows over top the split gate 609 and makes physical and conductive contact throughout its area at the contact interface. In FIG. 6C the wide contact plug 623 pierces the nitride layer 618 and makes physical and conductive contact with the split gate electrode 609 at an unsilicided contact interface 640.

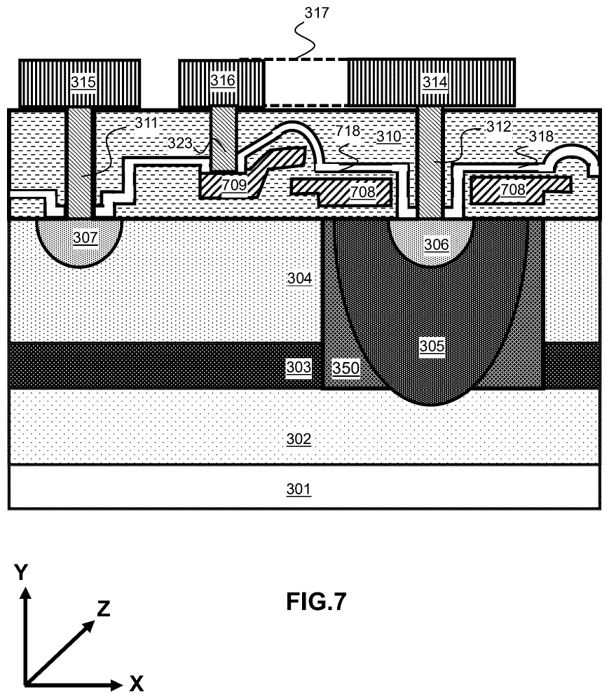

FIG. 7 is a side cross-section diagram of a split gate transistor device with a contact plug over the split gate with a portion of the split gate electrode formed over the gate electrode according to an aspect of the present disclosure. In this implementation the split gate 709 may be formed in a second split gate electrode deposition step after formation of the gate electrode 708 and deposition of insulating material over the gate electrode. A masking step and deposition step may be configured to create a region of the split gate electrode 709 that runs over top the gate electrode 708. In an alternative embodiment, not depicted, the split gate electrode may be formed first and covered with insulating material, a masking and deposition step may then create a gate electrode that includes a portion of gate electrode which runs overtop the split gate electrode. In some split gate layouts, the separation between the split gate and gate electrode causes HCI at the edge of the gate near the split gate, this implementation may reduce HCI on the edge of the gate electrode as it places the split gate electrode very close to the gate electrode. The nitride layer 718 may be formed over top split gate electrode 709 and the gate electrode 708 with some insulating located in between. One design consideration for this implementation is capacitive coupling of the split gate electrode to the gate electrode but generally this is not a concern because the split gate electrode is at source potential. Also, gate-source capacitance (Cgs) may be kept low by making the thickness of the dielectric (e.g. oxide) much thicker than gate oxide. While this implementation depicts a contact plug which pierces the nitride layer it should be understood that any contact plug configuration may be used with this implementation of split gate and gate electrodes.

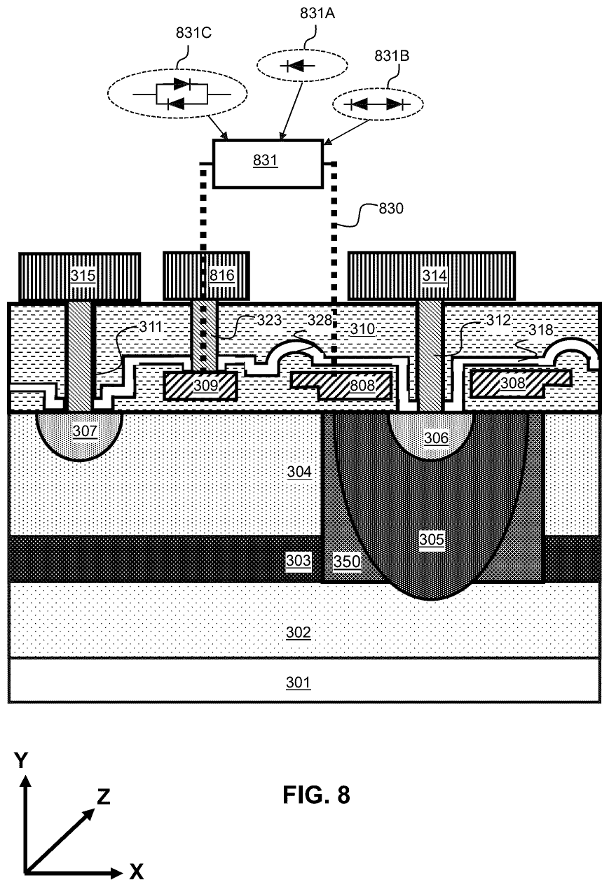

FIG. 8 is a side cross-section diagram of a split gate transistor device with a contact plug over the split gate conductively coupled to the gate by at least one diode according to an aspect of the present disclosure. In this implementation the split gate electrode 309 is connected 830 to the gate electrode 808 through at least one diode 831. In some implementations, instead of a single diode 831A, two diodes in back-to-back configuration 831B may be connected between the gate electrode and the split gate electrode 309. Alternatively, two diodes in anti-parallel configuration 831C may be connected between the gate electrode and split gate electrode. In yet other alternative implementations, two or more pairs of diodes in either back-to-back configuration or anti-parallel configuration may be connected between the split gate electrode and the gate electrode. In some implementations the gate electrode 808 may be connected by a conductive connection 830, such as a wire or metal trace, to at least one diode 831 by a wire attached at a gate electrode contact region and a second wire may connect the one of the at least one diode 831 to the split gate or the split gate metal layer 816. The one or more diodes may be located off the device or formed in the split gate via doping of alternating P-type and N-type regions near the wire contact site. Alternatively, the gate electrode 808 may be connected to the split gate electrode by a wire from gate metal (not shown). Such implementations may reduce capacitance compared to other implementations and the diode may provide accumulation effect to reduce on-resistance as this implementation may not cause Gate Drain Capacitance (CGD).

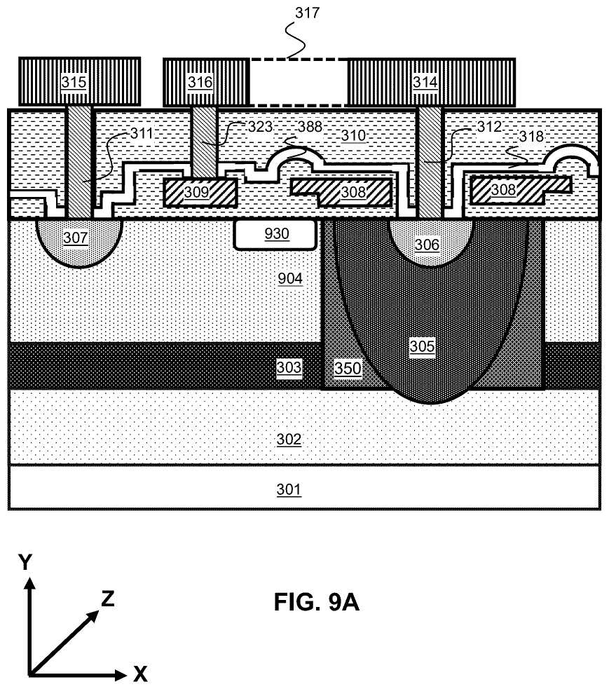

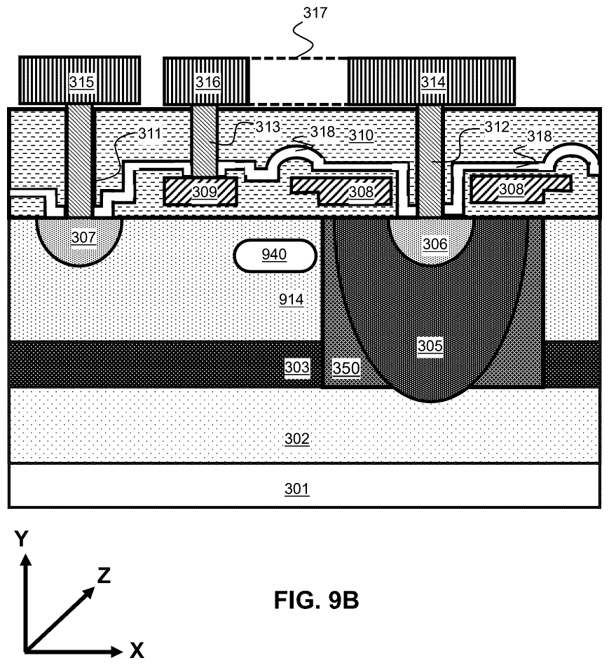

FIG. 9A is a side cross-section diagram of a split gate transistor device with a contact plug over the split gate and extended surface drift implant region according to an aspect of the present disclosure. In this implementation an extra implant region 930 of ions having the second conductivity type is formed near the surface of the upper drift region 904. As shown in FIG. 9A, an upper portion of the implant region 930 is at the surface of the upper drift region 904. The implantation dose may be adjusted to make region 930: (1) a p-type region or (2) still n-type but at lower concentration, even low enough to be considered un-doped. This extended surface drift implant region 930 reduces the carrier concentration near the edge of the gate electrode 308 and thus may reduce the HCI at the edge of the gate electrode and improve BVdss. The extra implant region may be formed in the upper drift region via ion implantation with an implant energy chosen to place the region near the top surface of the substrate composition.

FIG. 9B is a side cross-section diagram of a split gate transistor device with a contact plug over the split gate and extended deep drift implant region according to an aspect of the present disclosure. In this implementation an extra implant region 940 of ions having the second conductivity type is formed deep (Y-direction) in the upper drift region 914. This extended surface drift implant region 940 reduces the carrier concentration near the edge of the gate electrode 308 and thus may reduce the HCI at the edge of the gate electrode and improve BVdss. Unlike the implant region 930 of FIG. 9A, an upper portion of the implant region 940 is below the surface of the upper drift region 914. If the extra implant is deep enough, the carrier concentration at the surface will not be reduced. Instead, the extra P-type implant 930 can create an effect called reduced surface field (RESURF) which in turn reduce the HCI and make the BV higher. The extra implant region may be formed in the upper drift region via ion implantation with an implant energy chosen to place the region deep in the upper drift region of the substrate composition.

While the previous two implementations show a small contact plug with extra implant region, aspects of the present disclosure are not so limited and thus the extra implant region may be used in implementations including a wide contact plug and/or multiple contact plugs.

FIG. 10 is a top-down view of a split gate transistor device with a contact plug and split gate according to an aspect of the present disclosure. As shown in this implementation the drain contact 1001 is formed over the drain contact region 1002 in the semiconductor substrate composition. The upper drift region 1003 in semiconductor substrate runs underneath the drain contact region 1002, drain contact 1001, gate electrode 1007 and the split gate electrode 1004. For case of description the insulation layer has been omitted from the view but it should be understood that the split gate electrode 1004 sits above the semiconductor substrate regions in the insulation layers and similarly the drain contact 1001, source contact 1011 and contact plug 1005 sit in the insulation layer. The conductive contact plug 1005 may be formed over the split gate electrode 1004 in this implementation the conductive contact plug is a small contact plug and thus does not extend over the substrate composition unlike some of the other examples discussed above. The contact plug 1005 may have a conductive connection to the split gate 1004 at an active contact region 1008 on the tip of the half oval finger formed by the split gate electrode 1004. In this active contact region 1008 a via through the insulation (not shown) and nitride layer (not shown), a portion of the contact plug may allow a portion of the conductive contact plug 1005 to make conductive and physical contact with the split gate 1004. Here, the active contact is shown in dotted lines to denote that it is optional and that alternative implementations are available. Additionally, as depicted by the dashed lines, the contact plug 1005 may extend around the half oval finger of the split gate electrode 1004 or may extend to over only a portion of the split gate electrode 1004 or may be limited to regions on the long sides of the half oval finger of the split gate electrode 1004. It should further be understood that in some implementations the half oval fingers may be complete ovals which surround the drain contact region 1002 and drain contact 1001. Additionally, aspects of the present disclosure are not limited to ovals and may include other shapes such as overlapping squares, rectangles, circles, and stripes of regions. In alternative implementations the conductive contact plug 1005 may pierce the nitride layer (not shown) and make conductive and physical contact with split gate 1004 at a contact interface that runs along the entire area of the of the conductive contact plug 1005. In this implementation there is a gap between the split gate 1004 and the gate electrode 1007 in the insulating layer. It should further be understood that this gap is filled with the material of the insulating layer. As shown the gate electrode 1007 also surrounds the split gate 1004 and the drain contact 1001. Additionally, the gate electrode stops before the source contact 1010 leaving a space between the gate electrode 1007 filled with insulating layer material, provides insulation to the source contact 1010 from the gate electrode 1007.

Although bar-type contact plugs 1005 are shown in FIG. 10, in some implementations, the contact plugs may be an array-type contact plug in the form of an array of plural individual contact plugs that extend in the z-direction.

A well region 1009 is formed in the semiconductor substrate near the upper drift region 1003 and the gate electrode 1007 runs over top a portion of the well region 1009. A source contact region 1010 is formed in the well region 1009 and the source contact 1011 makes conductive contact with the semiconductor substrate composition in the source contact region 1010. In some implementations the gate electrode 1007 may run over the well region 1009 and overlap a portion of the source region contact 1010. Here, for ease of viewing the metal layers have also been omitted from view.

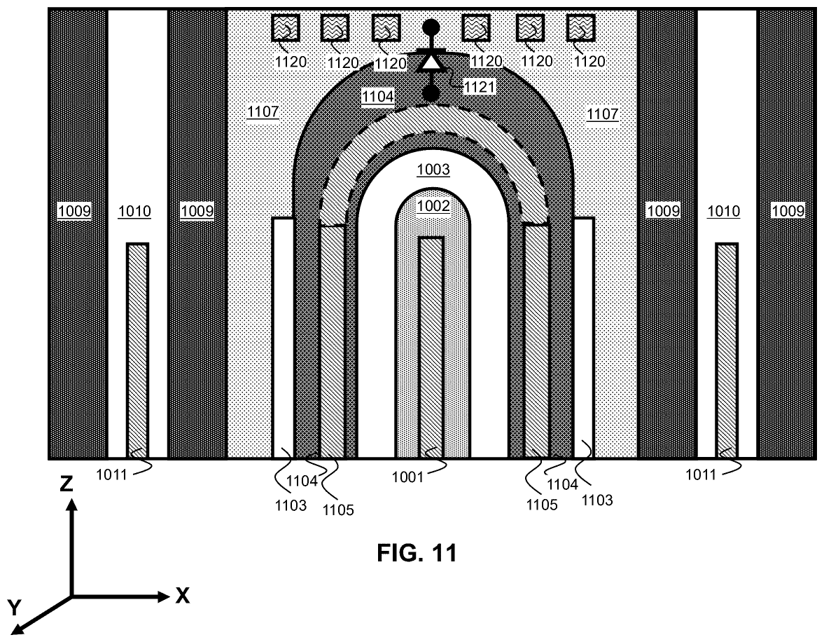

FIG. 11 is a top-down view of a split gate transistor device with a doped split gate electrode in contact with a doped gate electrode forming a diode between the split gate electrode and a the gate electrode. This top view may be an implementation of the side view of the split gate conductively coupled to the gate by at least one diode shown in FIG. 8 and also retains some features shown in FIG. 10. Here, the split gate electrode 1104 is fabricated from a semiconductor material doped with ions of the second conductivity type (for example and without limitation p-type). The gate electrode 1107 is also fabricated from a semiconductor material and impregnated with ions of the first conductivity type (for example and without limitation n-type). The split gate electrode 1104 is in contact with the gate electrode 1107 near the tip of the half oval fingers. The contact between the doped split gate electrode 1104 and the gate electrode 1107 forms a semiconductor diode 1121, for example a diode is formed with the p-type doped split gate electrode as the anode and the n-type doped electrode as the cathode. The gate electrode 1107 separates from contact with the split gate electrode 1104 away from the tip of the half oval fingers exposing to view the upper drift region 1103 underneath. It should be noted that the upper drift region 1003 is continuous with the exposed the upper drift region 1103 underneath the split gate electrode. The difference in labels here is simply for ease of description.

The contact plugs 1105 may have a z-direction length less than the length of the exposed upper drift region 1103. Not all implementations require this, however. For example, in some implementations the contact plugs 1105 need not be less than the length of the exposed drift region 1103. In fact, they can go around the tip of the upper drift region and join together, e.g., as shown by the portion outlined in dashed lines in FIG. 11. Although bar-type contact plugs 1105 are shown in FIG. 11, in some implementations, the contact plugs may be an array-type contact plug in the form of an array of plural individual contact plugs that extend in the z-direction.

Additionally, the gate contacts 1120 are shown in this implementation. For simplified viewing the gate contacts 1120 here, are shown close to the tip of the half oval split gate but it should be understood that there it would be preferable for there gate contacts to be located near an edge of the gate electrode with a greater amount of separation from the tip of the split gate electrode than is shown.

Thus, an improvement to Ron and HCI and better shielding between the drain contact and drain metal from the gate electrode may be obtained by using a contact plug over split gate design as discussed above. Additionally, the contact plug over split gate design may provide for an improved process flow as the split gate serves as an etch-stop for the contact plug reducing the likelihood of destroying the device during creation of the plug trench. Additionally, in the contact plug over split gate design the split gate contact may not need to silicided unlike the prior art split gate design, this reduces many design rule limitations that the prior art split gate design incurred due to the need for silicided split gate contact.

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A,” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A planar gate transistor device, comprising:
a semiconductor substrate;
a conductive gate electrode formed over the semiconductor substrate;
a conductive split gate electrode formed over the semiconductor substrate proximate a side of the conductive gate electrode near a drain contact;
a conductive contact plug formed over the split gate electrode.

2. The planar gate transistor device of claim 1 wherein the conductive contact plug makes conductive contact with the split gate in one or more split gate contact areas.

3. The planar gate transistor device of claim 2 wherein the one or more split gate contact areas are located near a tip of a finger formed by the conductive split gate.

4. The planar gate transistor device of claim 1 wherein the conductive contact plug makes physical and conductive contact with the conductive split gate at a contact interface wherein the contact interface runs throughout an area of the conductive contact plug.

5. The planar gate transistor of claim 1 wherein the conductive contact plug includes a barrier metal at a contact interface with the conductive split gate contact.

6. The planar gate transistor of claim 1 wherein the barrier metal includes one or more materials selected from a list consisting of Cobalt, Titanium-nitride, Tungsten-nitride, Tantalum, Ruthenium, Tantalum-nitride, and Indium-oxide.

7. The planar gate transistor of claim 1 further comprising a nitride layer over the conductive split gate electrode wherein the conductive contact plug intersects the nitride layer.

8. The planar gate transistor of claim 7 wherein the conductive contact plug pierces the nitride layer over the conductive split gate electrode.

9. The planar gate transistor of claim 1 wherein the conductive contact plug has a horizontal width smaller than a horizontal width of the drain contact.

10. The planar gate transistor of claim 1 wherein the conductive contact plug has a horizontal width that is equal to a horizontal width of the drain contact.

11. The planar gate transistor of claim 1 wherein the horizontal width of the conductive contact plug is less than 0.09 micrometers.

12. The planar gate transistor of claim 1 wherein the horizontal width of the conductive contact plug is greater than 0.1 micrometers.

13. The planar gate transistor of claim 1, wherein the conductive contact plug is a bar-type contact plug.

14. The planar gate transistor of claim 1, wherein the conductive contact plug is an array-type contact plug having plural contact plugs.

15. The planar gate transistor of claim 1 wherein the conductive contact plug extends from over the split gate electrode to an area over the semiconductor substrate not covered by the conductive split gate electrode.

16. The planar gate transistor of claim 1 including one or more additional conductive contact plugs formed over the semiconductor substrate.

17. The planar gate transistor of claim 16 wherein at least one of the one or more additional conductive contact plugs is formed over the semiconductor substrate in an area not covered by the conductive split gate electrode.

18. The planar gate transistor of claim 1 wherein the conductive contact plug is conductively coupled to a source contact.

19. The planar gate transistor of claim 1 wherein the conductive contact plug is conductively coupled to the gate electrode through at least one diode.

20. The planar gate transistor of claim 1 wherein the conductive contact plug is conductively coupled to the gate electrode through at least two diodes arranged in back-to-back configuration.

21. The planar gate transistor of claim 1 wherein the conductive contact plug is conductively coupled to the gate electrode through at least two diodes arranged in anti-parallel configuration.

22. The planar gate transistor of claim 1 wherein a portion of the conductive split gate is formed over the conductive gate.

23. The planar gate transistor of claim 1 wherein a portion of the conductive gate is formed over the conductive split gate.

24. The planar gate transistor of claim 1 wherein the conductive split gate electrode is made from material selected from a list consisting of N-type silicon, P-type silicon, undoped silicon, and a metal.

25. The planar transistor of claim 1 wherein the conductive split gate includes a metal selected from the list consisting of copper, chromium bismuth and any alloy of the listed metals.

26. The planar gate transistor of claim 25 wherein the conductive split gate includes a barrier metal.

27. The planar gate transistor of claim 1, further comprising an implant region of a conductivity type opposite that of an upper drift region of the semiconductor substrate formed near a surface of the upper drift region between the conductive gate electrode and the conductive split gate electrode, wherein an upper portion of the implant region is at the surface of the upper drift region.

28. The planar gate transistor of claim 1, further comprising an extra implant region of a conductivity type opposite that of an upper drift region of the semiconductor substrate formed below a surface of the upper drift region between the conductive gate electrode and the conductive split gate electrode, wherein an upper portion of the implant region is below the surface of the upper drift region.
